(19) United States
(12) Patent Application Publication
(10) Pub. No.: US 2015/0070043 A1
(43) Pub. Date: Mar. 12, 2015

(54) INSPECTION METHOD AND INSPECTION DEVICE OF INTEGRATED CIRCUIT DEVICE

(71) Applicant: KABUSHIKI KAISHA TOSHIBA, Tokyo (JP)

(72) Inventors: Tomokazu NAKAI, Kanagawa (JP); Kazuhiro IIZUKA, Kanagawa (JP)

(73) Assignee: KABUSHIKI KAISHA TOSHIBA, Tokyo (JP)

(21) Appl. No.: 14/194,622

(22) Filed: Feb. 28, 2014

(30) Foreign Application Priority Data
Sep. 12, 2013 (JP) 2013-189277

(51) Int. Cl. G01R 31/26

(52) U.S. Cl. CPC G01R 31/2601
USPC 324/762.01

(57) ABSTRACT

A method of inspecting a semiconductor device in which a plurality of conductive members is stacked includes drilling through the conductive layers using a drill and, while drilling, monitoring a probe device that is electrically connected to one of the conductive layers. When an electrical connection is established between the drill and probe device, the drilling is halted and said one of the conductive layers is inspected.

### CROSS-REFERENCE TO RELATED APPLICATION

This application is based upon and claims the benefit of priority from Japanese Patent Application No. 2013-189277, filed Sep. 12, 2013, the entire contents of which are incorporated herein by reference.

### FIELD

Embodiments described herein relate generally to an inspection method and an inspection device of an integrated circuit device.

### BACKGROUND

Recent memory devices have a structure where a plurality of conductive members are stacked, and memory cells are three-dimensionally integrated therein.

### DESCRIPTION OF THE DRAWINGS

FIG. 1 is a perspective view illustrating an integrated circuit device that is inspected according to an embodiment.

FIGS. 2(a) and (b) are cross-sectional views of the integrated circuit device of FIG. 1.

FIG. 3 is a view illustrating an inspection device according to a first embodiment.

FIG. 4 is a flowchart diagram illustrating an inspection method according to the first embodiment.

FIG. 5 is a view illustrating an inspection device according to a second embodiment.

FIG. 6 is a flowchart diagram illustrating an inspection method according to the second embodiment.

FIG. 7 is a view illustrating an inspection device according to a third embodiment.

FIG. 8 is a flowchart diagram illustrating an inspection method according to the third embodiment.

### DETAILED DESCRIPTION

Embodiments provide an inspection method and an inspection device which can inspect an integrated circuit device in which a plurality of conductive members are stacked.

In a first embodiment, an inspection method of a semiconductor device having a substrate and in which a plurality of conductive members are vertically stacked, includes the steps of drilling through the conductive layers using a drill and, while drilling, monitoring a probe device that is electrically connected to one of the conductive layers. The method further includes the steps of halting the drilling when an electrical connection is established between the drill and the probe device and, after halting the drilling, inspecting said one of the conductive layers.

According to another embodiment, an apparatus for inspecting a semiconductor device having a substrate and a plurality of conductive layers stacked above the substrate is provided. The apparatus comprises a drill, a probe device, and a controller configured to control the drill to drill through the conductive layers and halt the drilling when an electrical connection is established between the drill and the probe device. The apparatus further comprises an inspection device configured to inspect a conductive layer that has been exposed by the drilling.

According to still another embodiment, an apparatus for inspecting a semiconductor device having a substrate and a plurality of conductive layers stacked above the substrate, the apparatus is provided. The apparatus comprises a drill, a probe device, and a potential detection unit configured to detect a change in potential of one of the conductive layers and halt the drilling when a change in potential of said one of the conductive layers is detected. The apparatus further comprises an inspection device configured to inspect a conductive layer that has been exposed by the drilling.

### First Embodiment

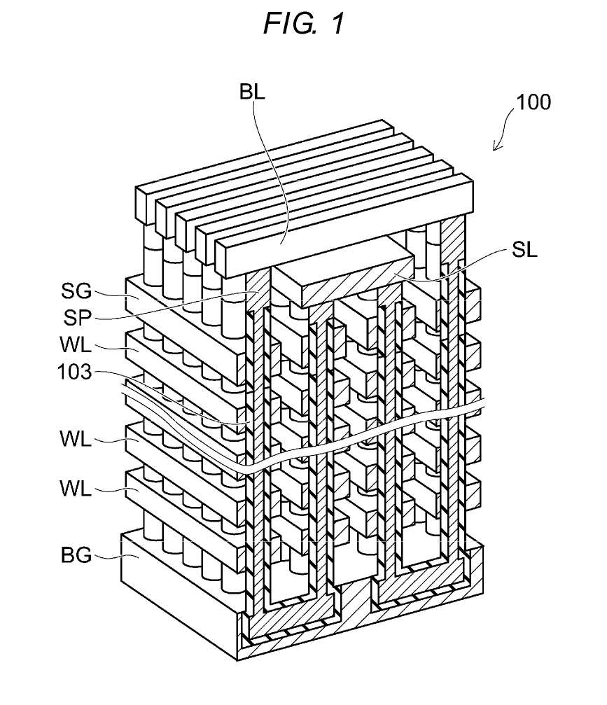

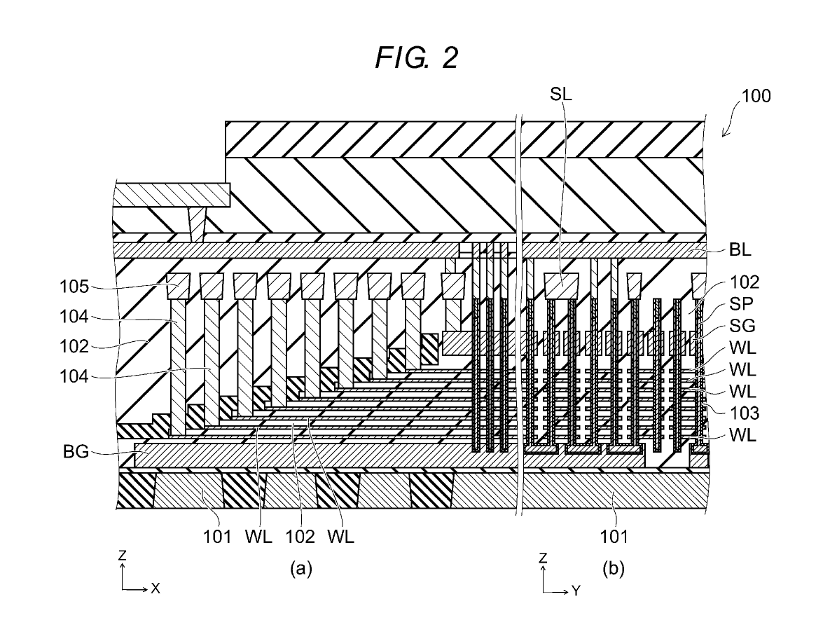

First, an example of an integrated circuit device that is inspected according to a first embodiment will be described. As illustrated in FIG. 1, and FIGS. 2(a) and (b), an integrated circuit device 100 that is inspected according to the first embodiment is a three-dimensional stack-type semiconductor memory device in which a plurality of conductive films are stacked.

For convenience of description, an XYZ orthogonal coordinate system is used in FIG. 1, and FIGS. 2(a) and (b).

In the device 100, a back gate electrode BG is installed on a silicon substrate 101. On the back gate electrode BG, a plurality of word lines WL, for example, 24 word lines WL, are stacked through an interlayer insulating film 102, and thereon, a selection gate electrode SG is installed. The back gate electrode BG, the word line WL and the selection gate electrode SG are all conductive films formed of silicon that contains impurities. A shape of the back gate electrode BG is a flat plate, and a shape of the word line WL and the selection gate electrode SG is a strip extending in the X direction. On the selection gate electrode SG, a source line SL, which is formed of, for example, metal and extends in the X direction, is installed. On the source line SL, a bit line BL which is formed of, for example, metal and extends in the Y direction, is installed.

In addition, a silicon pillar SP extending in the Z direction is installed between the back gate electrode BG and the source line SL, and between the back gate electrode BG and the bit line BL, so as to penetrate the plurality of word lines WL and the selection gate electrode SG. The silicon pillar SP connected to the source line SL, and the silicon pillar SP connected to the bit line BL are connected to each other within the back gate electrode BG. A memory film 103 in which a tunnel insulating layer, a charge storage layer and a block insulating layer are stacked in this order, is installed between the silicon pillar SP and the word line WL. Thus, in each intersection between the silicon pillar SP and the word line WL, a memory cell transistor is formed.

As illustrated in FIG. 2(a), each of the word lines WL is drawn in the X direction, and drawn upward by a via 104, respectively. On the upper side of the via 104, an upper layer wire 105 extending in the X direction is installed. Thus, each word line WL is connected to the upper layer wire 105 through the via 104.

In addition, a structure of the memory cell array is not limited to the above-described structure, and may be a structure of the memory cell array described in U.S. patent application Ser. No. 12/407,403, filed Mar. 19, 2009, entitled “Three Dimensional Stacked Nonvolatile Semiconductor Memory”. In addition, the structure of the memory cell array may be a structure of the memory cell array described in U.S. patent application Ser. No. 12/406,524, filed Mar. 18, 2009, entitled “Three Dimensional Stacked Nonvolatile Semiconductor Memory”, U.S. patent application Ser. No. 12/679,991, filed Mar. 25, 2010, entitled “Non-volatile Semiconductor Storage Device and Method of Manufacturing the Same”, or U.S. patent application Ser. No. 12/532,030, filed Mar. 23, 2009, entitled “Semiconductor Memory and Method for Manufacturing the Same”. All of the above-identified patent applications are incorporated herein by reference in their entirety.

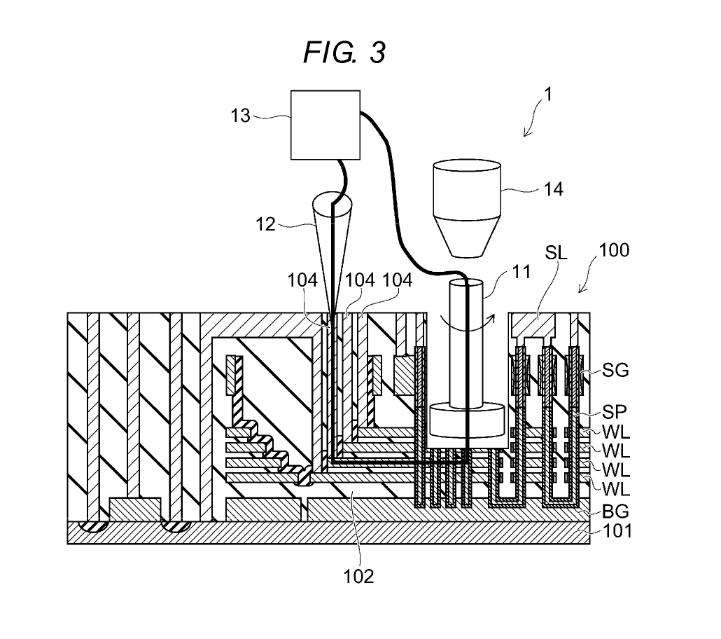

Next, an inspection device according to the first embodiment will be described. The inspection device according to the first embodiment inspects the above-described integrated circuit device 100, for example. As illustrated in FIG. 3, an inspection device 1 according to the first embodiment includes a microdrill 11, a microprobe 12, a detection unit 13, and a SEM (Scanning Electron Microscope) 14.

At least a tip of the microdrill 11 is formed of conductive material. The microdrill 11 is a grinding unit that locally grinds the integrated circuit device 100, for example, from a top surface side of the integrated circuit device 100. The tip of the microprobe 12 is brought into contact with the via 104 of the integrated circuit device 100, thereby enabling the tip to be connected to the word line WL. A power source and a current sensor are installed inside the detection unit 13. The detection unit 13 is connected to the microdrill 11 and the microprobe 12. Thus, the detection unit 13 applies a voltage between the microdrill 11 and the microprobe 12. When there is conduction between the microdrill 11 and the microprobe 12, the detection unit 13 can detect the conduction between the microdrill 11 and the microprobe 12. The surface of the integrated circuit device 100, which is ground by the microdrill 11, can be observed and then inspected by the SEM 14.

Next, an operation of the inspection device according to the first embodiment, that is, an inspection method according to the first embodiment, will be described.

For example, when a malfunction occurs in any memory cell transistors within the integrated circuit device 100, first, the memory cell transistor in which the malfunction occurred is specified by an electrical unit. Next, for example, the integrated circuit device 100 is ground from the top surface side thereof, and then each member which forms the memory cell transistor in which the malfunction occurred is exposed. Then, each member is observed by the SEM or the like, so that an actually occurring phenomenon may be observed.

However, since the word lines WL in the integrated circuit device 100, which are of identical shape, are stacked vertically in a plurality of layers, when the integrated circuit device 100 is ground from the top surface side, whether or not the word line WL exposed at the ground surface is the word line WL which is to be inspected cannot be determined. In other words, whether or not the ground surface reached is the ground surface to be inspected is not easily determined.

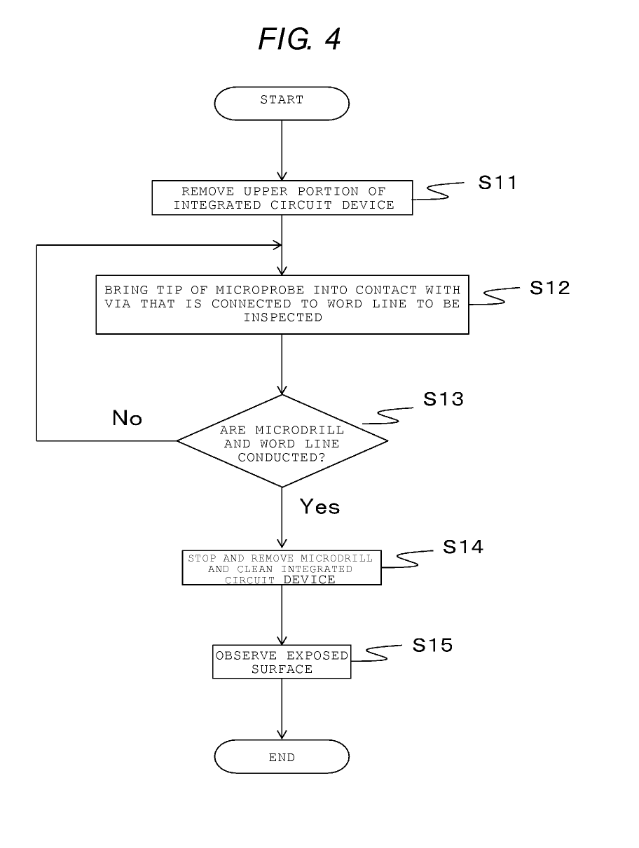

Therefore, in the first embodiment, as illustrated in step S11 of FIG. 4, an upper portion of the integrated circuit device 100 is removed. Specifically, an upper surface of the integrated circuit device 100 is ground, whereby the bit line BL, the source line SL and the upper layer wire 105 are removed, so that the via 104 is exposed.

Next, as illustrated in step S12, the tip of the microprobe 12 comes into contact with the via 104 connected to the word line WL which is to be inspected. Next, the detection unit 13 applies a voltage between the microdrill 11 and the microprobe 12. In this state, an upper portion of the memory cell transistor which is to be inspected in the integrated circuit device 100 is ground by the microdrill 11 from the upper surface side thereof.

Then, as illustrated in step S13, when the tip of the microdrill 11 reaches the word line WL which is to be inspected, it is determined whether there is conduction between the microdrill 11 and the word line WL. When a closed circuit including the detection unit 13, the microprobe 12, the via 104, the word line WL and the microdrill 11 is formed, a current flows in the closed circuit. The detection unit 103 detects the current, whereby the detection unit 103 can detect that the microdrill 11 has reached a target. When detecting conduction between the microdrill 11 and the microprobe 12, the detection unit 103 stops the microdrill 11.

Next, as illustrated in step S14, the microdrill 11 is removed from the integrated circuit device 100, and then the integrated circuit device 100 is cleaned and dried. Next, as illustrated in step S15, the exposed surface, which is exposed by the above-described grinding, in the integrated circuit device 100 is observed by the SEM 14. Thus, the memory cell transistor in which the malfunction occurred is inspected by the SEM observation.

According to the first embodiment, even in the integrated circuit device 100 in which the identically shaped word lines WL are stacked in the plurality of layers, the word line WL which is to be inspected object may be reliably found. Thus, the portion in which the malfunction occurred may be inspected quickly and reliably.

In addition, in the first embodiment, an example where the microprobe 12 comes into contact with the via 104 is described, but the first embodiment is not limited to this. For example, the microprobe 12 may directly come into contact with the word line WL. In addition, in the first embodiment, an example where the malfunction occurred in the memory cell transistor is described. However, the first embodiment is not limited to situations where a malfunction occurs in the memory cell transistor. Even when the malfunction occurs in the back gate electrode BG, the selection gate electrode SG, the source line SL, or the bit line BL, the inspection device and the inspection method according to the first embodiment may be applied. Furthermore, the inspection device is not limited to a SEM, but may also be an optical microscope, for example.

### Second Embodiment

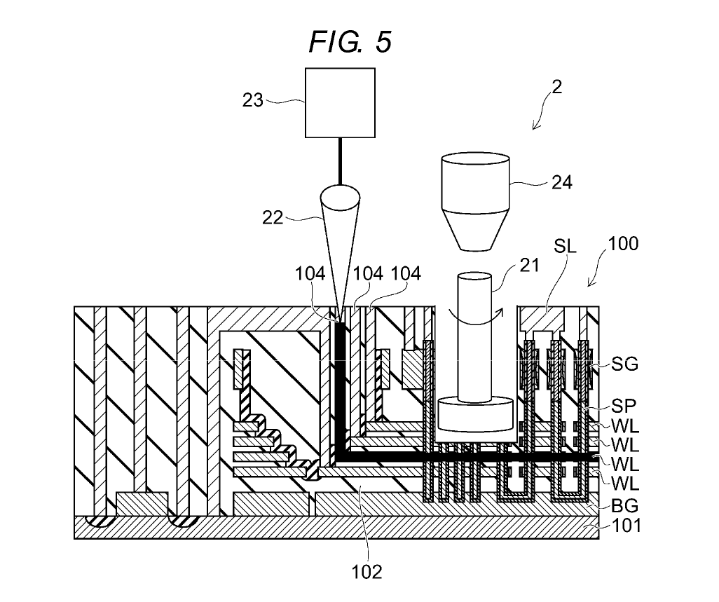

As illustrated in FIG. 5, in an inspection device 2 according to the second embodiment, a microdrill 21, a microprobe 22, a power supply device 23 and a SEM 24 are depicted. The microdrill 21 is a grinding unit which locally grinds the integrated circuit device 100, but a tip of the microdrill 21 may not necessarily be conductive. The power supply device 23 is connected to the microprobe 22, and applies a predetermined potential to the microprobe 22. Configurations of the microprobe 22 and the SEM 24 are identical to the microprobe 12 and the SEM 14 according to the first embodiment described above.

Next, an operation of the inspection device according to the second embodiment, that is, an inspection method according to the second embodiment, will be described.

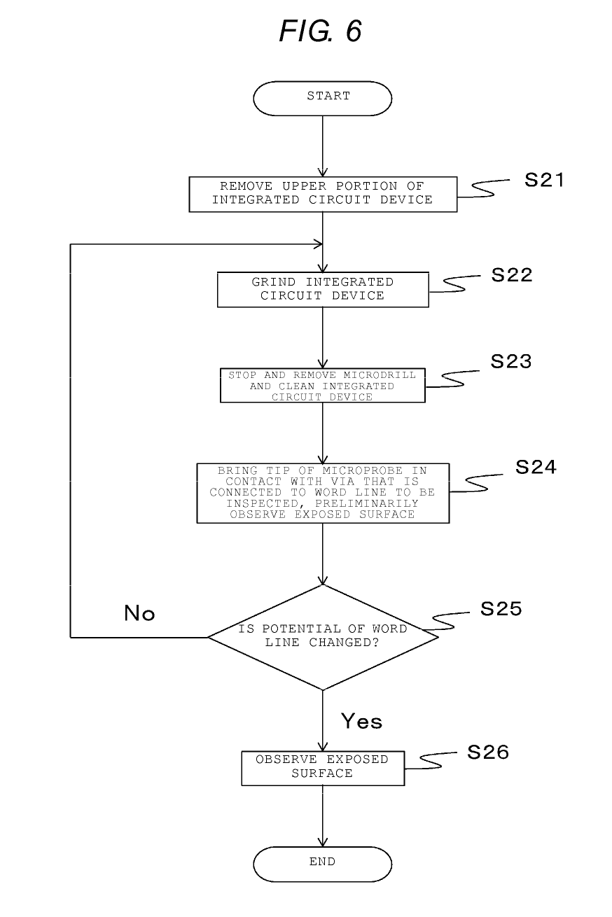

First, as illustrated in step S21 of FIG. 6, the upper portion of the integrated circuit device 100 is removed and the via 104 is exposed.

Next, as illustrated in step S22, the direct upper area of the portion of the integrated circuit device 100, which is to be inspected, is ground by the microdrill 21 from the upper surface side thereof. Then, when a certain amount of grinding is completed, as illustrated in step S23, the microdrill 21 is removed from the integrated circuit device 100, and then the integrated circuit device 100 is cleaned and dried.

Next, as illustrated in step S24, the tip of the microprobe 22 comes into contact with the via 104 connected to the word line WL to be inspected. Then, the power supply device 23 applies a potential to the word line WL to be inspected, through the microprobe 22 and the via 104. In this state, the surface exposed due to the grinding is preliminarily observed by the SEM 24.

At this time, when the word line WL which is observed by the SEM 24 is the word line WL to which the potential is applied by the power supply device 23, the potential of the observed word line WL differs from the potential of other word lines WL. Thus, it is possible to determine that the observed word line WL is the word line WL which is to be inspected.

Next, as illustrated in step S25, when there is no difference in the potential of the word line WL, it is determined that the ground surface has not reached the word line WL which is to be inspected. Thus, the process returns to step S22 and the grinding is continued. On the other hand, when there is a difference in the potential of the word line WL, it is determined that the ground surface has reached the word line WL which is to be inspected. Thus, the process proceeds to step S26 and the word line WL is observed.

Thus, until the ground surface reaches the word line WL with a difference in potential from the other word lines, the processes illustrated in steps S22 to S25 are repeated, whereby the memory cell transistor in which the malfunction occurred can be reliably inspected.

In addition, the second embodiment may be performed in combination with the first embodiment described above. For example, in a state where a voltage is applied between a word line just above the word line which is to be inspected and the microdrill, the integrated circuit device may be ground, and when there is conduction between the microdrill and the microprobe, the grinding may be stopped, thereafter a potential may be applied to the word line which is to be inspected, and then the word line may be observed by the SEM. Thus, the grinding is temporarily stopped just before the word line which is the inspection object, and thereafter careful grinding is performed, whereby accurate grinding to the target position can be performed. In addition, in a state where an interlayer insulating film remains on the word line which is to be inspected, the observation can be performed. Thus, the word line which is to be inspected is prevented from being damaged by the grinding and a more accurate inspection can be performed.

### Third Embodiment

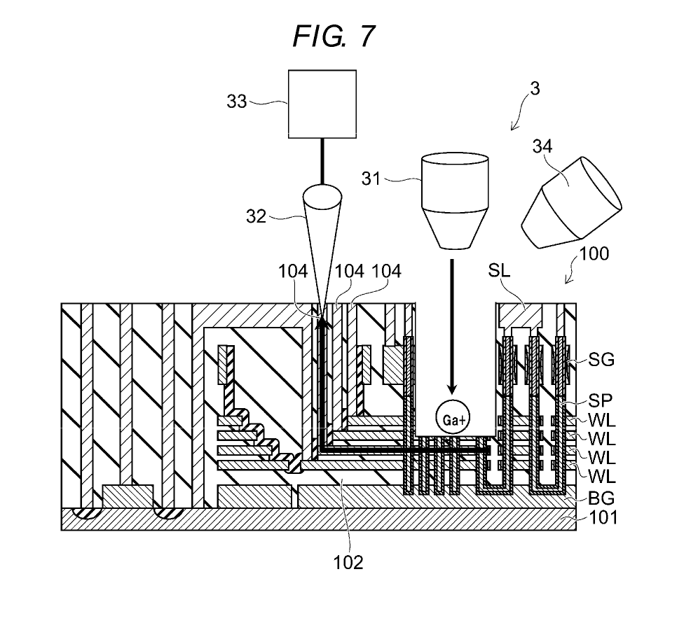

As illustrated in FIG. 7, in an inspection device 3 according to the third embodiment, a Focused Ion Beam (FIB) device 31, a microprobe 32, a potential detection unit 33, and a SEM 34 are provided. The FIB device 31 is a grinding unit for microfabrication which emits charged particles such as gallium ions (Ga⁺). The potential detection unit 33 includes an amplifier and a sensor, is connected to the microprobe 32, and is a unit that detects the potential of the microprobe 32. Configurations of the microprobe 32 and the SEM 34 are identical to the microprobe 12 and the SEM 14 according to the first embodiment described above. In addition, instead of the SEM 34, an optical microscope may be used. The FIB device 31, the microprobe 32 and the SEM 34 are arranged within a common vacuum chamber (not illustrated).

Next, an operation of the inspection device according to the third embodiment, that is, an inspection method according to the third embodiment, will be described.

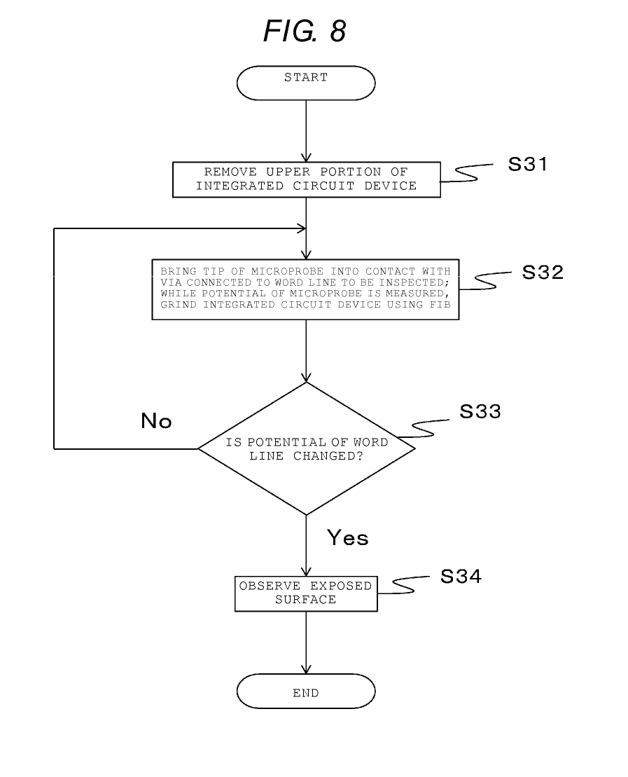

First, as illustrated in step S31 of FIG. 8, an upper portion of the integrated circuit device 100 is roughly ground to be removed, and the via 104 is exposed.

Next, as illustrated in step S32, a tip of the microprobe 32 comes into contact with the via 104 connected to the word line WL to be inspected. Then, the potential detection unit 33 operates and the potential of the microprobe 32 is measured. In this state, the FIB device 31 emits the gallium ions on the integrated circuit device 100, whereby the integrated circuit device 100 is ground from the upper surface side thereof.

Then, when a ground surface ground by the FIB device 31 reaches the word line WL which is to be inspected, the charge of the gallium ions flows into the word line WL, and the potential of the word line WL changes to be positive. In step S33, the potential detection unit 33 detects the potential change of the word line WL through the microprobe 32 and the via 104. If the potential change is detected, the emission of the gallium ions performed by the FIB device 31 is stopped. Thus, the grinding is stopped.

Next, as illustrated in step S34, the exposed surface exposed by the above-described grinding is observed by the SEM 34. Thus, the memory cell transistor in which the malfunction occurred can be inspected by the SEM observation.

Also, according to the third embodiment, the same advantage as the first embodiment described above may be obtained.

In addition, in the third embodiment, an example where the FIB device 31 emits the gallium ions is described, but the charged particles being used for the grinding are not limited to gallium ions.

In addition, in the first to third embodiments described above, the integrated circuit device which is to be inspected is not limited to the above-described device 100. For example, ReRAM (Resistance Random Access Memory) of cross-point structure may be inspected, and an integrated circuit device other than the memory device may be inspected.

According to the above-described embodiments, the inspection device and the inspection method which can inspect the integrated circuit device in which a plurality of conductive films are stacked can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of inspecting a semiconductor device including a substrate and a plurality of conductive layers stacked in a first direction perpendicular to the substrate, the method comprising:
drilling through the conductive layers by using a drill;
while drilling, monitoring an output of a probe device that is electrically connected to at least one of the conductive layers;
halting the drilling when an electrical connection is established between the drill and the probe device; and
after halting the drilling, inspecting said one of the conductive layers.

2. The method of claim 1, further comprising positioning the probe device to be electrically connected to said one of the conductive layers.

3. The method of claim 1, wherein said inspecting is performed by using a scanning electron microscope.

4. The method of claim 1, wherein the semiconductor device is a memory device and each of the conductive layers is a word line of the memory device.

5. The method of claim 1, further comprising:
after halting the drilling, cleaning the semiconductor device.

6. The method of claim 1, further comprising:
before drilling through the conductive layers, removing an upper portion of the semiconductor device.

7. The method of claim 1, wherein the drill has a conductive tip, and further comprising applying a voltage between the drill and the probe device.

8. The method of claim 1, wherein the drill has a non-conductive tip, and further comprising:
applying an electrical potential to one of the conductive layers;
detecting an electrical potential for each conductive layer exposed by the drilling; and
halting the drilling when the electrical potential detected for one of the conductive layers exposed by the drilling is different from the electrical potentials detected for the other conductive layers exposed by the drilling.

9. The method of claim 8, wherein the electrical potential for each conductive layer exposed by the drilling is detected by an electron microscope.

10. An apparatus for inspecting a semiconductor device including a substrate and a plurality of conductive layers stacked above the substrate, the apparatus comprising:
a drill;
a probe device;
a controller configured to control the drill to drill through the conductive layers and halt the drilling when an electrical connection is established between the drill and the probe device; and
an inspection device configured to inspect a conductive layer that has been exposed by the drilling.

11. The apparatus of claim 10, wherein the probe device is electrically connected to the conductive layer that has been exposed by the drilling.

12. The apparatus of claim 10, wherein the inspection device is a scanning electron microscope.

13. The apparatus of claim 10, wherein the semiconductor device is a memory device and each of the conductive layers is a word line of the memory device.

14. The apparatus of claim 10, wherein the drill has a conductive tip and the controller is configured to apply a voltage between the drill and the probe device.

15. An apparatus for inspecting a semiconductor device including a substrate and a plurality of conductive layers stacked above the substrate, the apparatus comprising:
a grinding unit configured to grind an upper surface of the conductive layers;
a probe device;
a potential detection unit configured to detect a change in potential of one of the conductive layers as the grinding unit grinds the upper surface of the conductive layer and halt grinding when a change in potential of said one of the conductive layers is detected; and
an inspection device configured to inspect a conductive layer that has been exposed by the grinding.

16. The apparatus of claim 15, wherein the grinding unit is configured to emit charged particles and the grinding comprises the emission of charged particles on to the semiconductor device.

17. The apparatus of claim 16, wherein the potential detection unit is configured to halt emission of charged particles from the drill when a change in potential of said one of the conductive layers is detected.

18. The apparatus of claim 16, wherein the grinding unit is a focused ion beam device.

19. The apparatus of claim 18, wherein the charged particles are gallium ions.

20. The apparatus of claim 15, wherein the probe device is electrically connected to the conductive layer that has been exposed by the grinding.
